(19) United States
(12) Patent Application Publication
(10) Pub. No.: US 2013/0217240 A1
(43) Pub. Date: Aug. 22, 2013

(54) FLOWABLE SILICON-CARBON-NITROGEN LAYERS FOR SEMICONDUCTOR PROCESSING

(71) Applicants: Abhijit Basu Mallick, Palo Alto, CA (US); Nitin K. Ingle, San Jose, CA (US); Linlin Wang, Fremont, CA (US); Brian S. Underwood, Santa Clara, CA (US)

(72) Inventors: Abhijit Basu Mallick, Palo Alto, CA (US); Nitin K. Ingle, San Jose, CA (US); Linlin Wang, Fremont, CA (US); Brian S. Underwood, Santa Clara, CA (US)

(73) Assignee: Applied Materials, Inc., Santa Clara, CA (US)

(21) Appl. No.: 13/590,611

(22) Filed: Aug. 21, 2012

Related U.S. Application Data
(60) Provisional application No. 61/536,380, filed on Sep. 19, 2011.
(60) Provisional application No. 61/532,708, filed on Sep. 9, 2011.
(60) Provisional application No. 61/550,755, filed on Oct. 24, 2011.
(60) Provisional application No. 61/567,738, filed on Dec. 7, 2011.

(51) Int. Cl. H01L 21/02

(52) U.S. Cl. CPC H01L 21/02274
USPC 438/778

(57) ABSTRACT

Methods are described for forming a dielectric layer on a semiconductor substrate. The methods may include providing a silicon-containing precursor and an energized nitrogen-containing precursor to a chemical vapor deposition chamber. The silicon-containing precursor and the energized nitrogen-containing precursor may be reacted in the chemical vapor deposition chamber to deposit a flowable silicon-carbon-nitrogen material on the substrate. The methods may further include treating the flowable silicon-carbon-nitrogen material to form the dielectric layer on the semiconductor substrate.

### CROSS-REFERENCES TO RELATED APPLICATIONS

This application claims the benefit of U.S. Provisional Application No. 61/536,380, filed Sep. 19, 2011, and titled “FLOWABLE SILICON-AND-CARBON-CONTAINING LAYERS FOR SEMICONDUCTOR PROCESSING.” This application also claims the benefit of U.S. Provisional Application No. 61/532,708 by Mallick et al. filed Sep. 9, 2011 and titled “FLOWABLE SILICON-CARBON-NITROGEN LAYERS FOR SEMICONDUCTOR PROCESSING.” This application also claims the benefit of U.S. Provisional Application No. 61/550,755 by Underwood et al, filed Oct. 24, 2011 and titled “TREATMENTS FOR DECREASING ETCH RATES AFTER FLOWABLE DEPOSITION OF SILICON-CARBON-AND-NITROGEN-CONTAINING LAYERS.” This application also claims the benefit of U.S. Provisional Application No. 61/567,738 by Underwood et al, filed Dec. 7, 2011 and titled “DOPING OF DIELECTRIC LAYERS.” Each of the above U.S. Provisional applications is incorporated herein in its entirety for all purposes.

### BACKGROUND OF THE INVENTION

The miniaturization of semiconductor circuit elements has reached a point where feature sizes of 45 nm, 32 nm, and even 28 nm are fabricated on a commercial scale. As the dimensions continue to get smaller, new challenges arise for seemingly mundane process steps like filling a gap between circuit elements with a dielectric material that acts as electrical insulation. As the width between the elements continues to shrink, the gap between them often gets taller and narrower, making the gap difficult to fill without the dielectric material getting stuck to create voids and weak seams. Conventional chemical vapor deposition (CVD) techniques often experience an overgrowth of material at the top of the gap before it has been completely filled. This can create a void or seam in the gap where the depositing dielectric material has been prematurely cut off by the overgrowth; a problem sometimes referred to as breadloafing.

One solution to the breadloafing problem has been to use liquid precursors for the dielectric starting materials that more easily pour into the gaps like filling a glass with water. A technique currently in commercial use for doing this is called spin-on-glass (SOG) and takes a liquid precursor, usually an organo-silicon compound, and spin coats it on the surface of a substrate wafer. While the liquid precursor has fewer breadloafing problems, other problems arise when the precursor material is converted to the dielectric material. These conversions often involve exposing the deposited precursor to conditions that split and drive out the carbon groups in the material, typically by reacting the carbon groups with oxygen to create carbon monoxide and dioxide gas that escapes from the gap. These escaping gases can leave behind pores and bubbles in the dielectric material similar to the holes left behind in baked bread from the escaping carbon dioxide. The increased porosity left in the final dielectric material can have the same deleterious effects as the voids and weak seams created by conventional CVD techniques.

More recently, techniques have been developed that impart flowable characteristics to dielectric materials deposited by CVD. These techniques can deposit flowable precursors to fill a tall, narrow gap without creating voids or weak seams, while avoiding the need to outgas significant amounts of carbon dioxide, water, and other species that leave behind pores and bubbles. Exemplary flowable CVD techniques have used carbon-free silicon precursors that require very little carbon removal after the precursors have been deposited in the gap.

While the new flowable CVD techniques represent a significant breakthrough in filling tall, narrow (i.e., high-aspect ratio) gaps with dielectric materials such as silicon oxide, there is still a need for techniques that can seamlessly fill such gaps with carbon-rich, low-κ dielectric materials. These materials generally have a lower dielectric constant (κ) than a pure silicon oxide or nitride, and typically achieve those lower κ levels by combining silicon with carbon species. Among other topics, the present application addresses this need by describing flowable CVD techniques for forming silicon-and-carbon containing dielectric materials on a substrate.

### BRIEF SUMMARY OF THE INVENTION

Methods are described for forming and curing a flowable silicon-carbon-nitrogen (Si—C—N) layer on a semiconductor substrate. The silicon and carbon constituents may come from a silicon and carbon containing precursor while the nitrogen may come from a nitrogen-containing precursor that has been activated to speed the reaction of the nitrogen with the silicon-and-carbon-containing precursor at lower deposition chamber temperatures. Exemplary precursors include 1,3,5-trisilapentane (H₃Si—CH₂—SiH₂—CH₂—SiH₃) as the silicon-and-carbon-containing precursor and plasma activated ammonia (NH₃) as the nitrogen-containing precursor. 1,4,7-trisilaheptane may be used to replace or augment the 1,3,5-trisilapentane. When these precursors react in the deposition chamber, they deposit a flowable Si—C—N layer on the semiconductor substrate. In those parts of the substrate that are structured with high-aspect ratio gaps, the flowable Si—C—N material may be deposited into those gaps with significantly fewer voids and weak seams.

The initial deposition of the flowable Si—C—N may include significant numbers of Si—H and C—H bonds. These bonds are reactive with the moisture and oxygen in air, as well as a variety of etchants which contributes to an increased rate of film aging and contamination, and higher wet-etch-rate-ratios (WERRs) for the etchants. Following deposition, the Si—C—N film may be cured to reduce the number of Si—H bonds while also increasing the number Si—Si, Si—C, and/or Si—N bonds in the final film. The curing may also reduce the number of C—H bonds and increases the number of C—N and/or C—C bonds in the final film. Curing techniques include exposing the flowable Si—C—N film to a plasma, such as an inductively coupled plasma (e.g., an HDP-CVD plasma) or a capacitively-coupled plasma (e.g., a PE-CVD plasma). In some embodiments, the deposition chamber may be equipped with an in-situ plasma generating system to perform the plasma treatment following the deposition without removing the substrate from the chamber. Alternately, the substrate may be transferred to a plasma treatment unit in the same fabrication system without breaking vacuum and/or being removed from system. This allows the curing step to occur before the initially deposited Si—C—N film has been exposed to moisture and oxygen from the air.

The final Si—C—N film may exhibit increased etch resistance to both conventional oxide and nitride dielectric etchants. For example, the Si—C—N film may have better etch resistance to a dilute hydrofluoric acid solution (DHF) than a silicon oxide film, and also have better etch resistance to a hot phosphoric acid solution than a silicon nitride film. The increased etch resistance to both conventional oxide and nitride etchants allows these Si—C—N films to remain intact during process routines that expose the substrate to both types of etchants.

Embodiments of the invention include methods of forming a dielectric layer on a semiconductor substrate. The methods may include the step of providing a silicon-containing precursor and an energized nitrogen-containing precursor to a chemical vapor deposition chamber. The silicon-containing precursor and the energized nitrogen-containing precursor may be reacted in the deposition chamber to deposit a flowable silicon-carbon-nitrogen material on the substrate. The method may further include treating the flowable silicon-carbon-nitrogen material to form the dielectric layer on the semiconductor substrate.

Embodiments of the invention may further include methods of treating a flowable silicon-carbon-nitrogen layer to reduce a wet etch rate ratio (WERR) of the layer. The methods may include forming the flowable silicon-carbon-nitrogen layer on a substrate by chemical vapor deposition of a silicon-containing precursor and an activated nitrogen precursor. They may further include exposing the flowable silicon-carbon-nitrogen layer to plasma, where the plasma exposure reduces the number of Si—H bonds and increases the number of Si—C bonds in the layer, and where the plasma exposure reduces the WERR of the layer.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps in a method of forming a silicon-carbon-nitrogen containing dielectric layer on a substrate;

FIG. 2 shows a substrate processing system according to embodiments of the invention;

FIG. 3A shows a substrate processing chamber according to embodiments of the invention;

FIG. 3B shows a gas distribution showerhead according to embodiments of the invention; and

FIG. 4 shows an infrared spectra of a silicon-carbon-nitrogen film before and after undergoing a plasma treatment.

### DETAILED DESCRIPTION OF THE INVENTION

Methods are described for applying flowable CVD techniques to the formation of flowable silicon-carbon-nitrogen containing materials. These flowable Si—C—N films may be further treated to form Si—C—N blanket layers, gapfills, and sacrificial barriers (among other elements) useful in the fabrication of integrated circuits.

### Exemplary Si—C—N Formation Methods

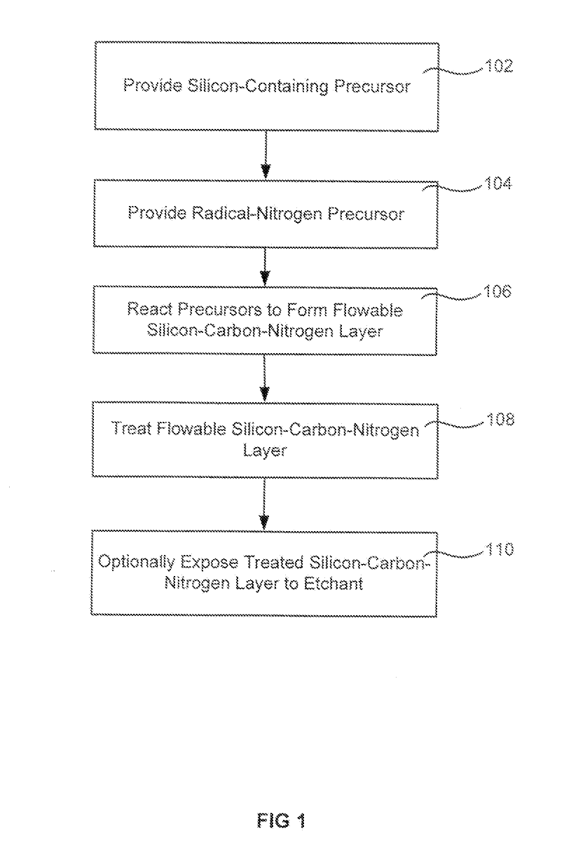

Referring now to FIG. 1, selected steps in a method of forming a silicon-carbon-nitrogen containing dielectric layer on a substrate. The method may include the step of providing a silicon-containing precursor 102 to a chemical vapor deposition chamber. The silicon-containing precursor may provide the silicon constituent to the deposited Si—C—N film, and may also provide the carbon component. Exemplary silicon-containing precursors include 1,3,5-trisilapentane, 1,4,7-trisilaheptane, disilacyclobutane, trisilacyclohexane, 3-methylsilane, silacyclopentene, silacyclobutane, and trimethylsilylacetylene, among others:

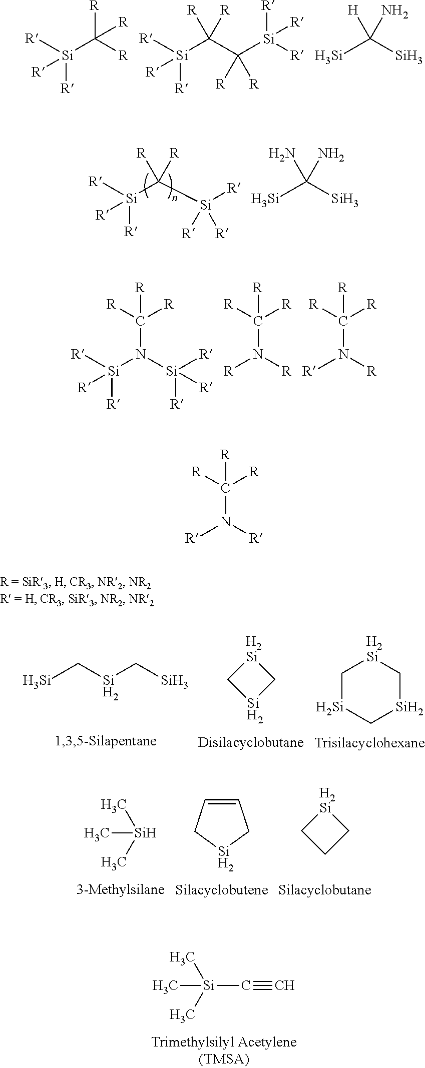

Additional exemplary silicon-containing precursors may include mono-, di-, tri-, tetra-, and penta-silanes where one or more central silicon atoms are surrounded by hydrogen and/or saturated and/or unsaturated alkyl groups. Examples of these precursors may include SiR₄, Si₂R₆, Si₃R₈, Si₄R₁₀, and Si₅R₂, where each R group is independently hydrogen (—H) or a saturated or unsaturated alkyl group. Specific examples of these precursors may include without limitation the following structures:

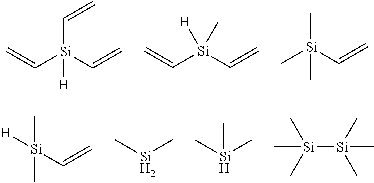

More exemplary silicon-containing precursors may include disilylalkanes having the formula R₃Si—[CR₂]ₓ—SiR₃, where each R is independently a hydrogen (—H), alkyl group (e.g., —CH₃, —CₘH₂ₘ₊₂, where m is a number from 1 to 10), unsaturated alkyl group (e.g., —CH═CH₂), and where x is a number for 0 to 10. Exemplary silicon precursors may also include trisilanes having the formula R₃Si—[CR₂]ₓ—SiR₂—[CR₂]_{y}—SiR₃, where each R is independently a hydrogen (—H), alkyl group (e.g., —CH₃, —CₘH₂ₘ₊₂, where m is a number from 1 to 10), unsaturated alkyl group (e.g., —CH═CH₂), and where x and y are independently a number from 0 to 10. Exemplary silicon-containing precursors may further include silylalkanes and silylalkenes of the form R₃Si—[CH₂]ₙ—[SiR₃]ₘ—[CH₂]ₙ—SiR₃, wherein n and m may be independent integers from 1 to 10, and each of the R groups are independently a hydrogen (—H), methyl (—CH₃), ethyl (—CH₂CH₃), ethylene (—CHCH₂), propyl (—CH₂CH₂CH₃), isopropyl (—CHCH₃CH₃), etc.

Exemplary silicon-containing precursors may further include polysilylalkane compounds may also include compounds with a plurality of silicon atoms that are selected from compounds with the formula R—[(CR₂)ₓ—(SiR₂)_{y}—(CR₂)_{z}]ₙ—R, wherein each R is independently a hydrogen (—H), alkyl group (e.g., —CH₃, —CₘH₂ₘ₊₂, where m is a number from 1 to 10), unsaturated alkyl group (e.g., —CH═CH₂), or silane group (e.g. —SiH₃, —(Si₂H₂)ₘ—SiH₃, where m is a number from 1 to 10)), and where x, y, and z are independently a number from 0 to 10, and n is a number from 0 to 10. In disclosed embodiments, x, y, and z are independently integers between 1 and 10 inclusive. x and z are equal in embodiments of the invention and y may equal 1 in some embodiments regardless of the equivalence of x and z. n may be 1 in some embodiments.

For example when both R groups are —SiH₃, the compounds will include polysilylalkanes having the formula H₃Si—[(CH₂)ₓ—(SiH₂)_{y}—(CH₂)_{z}]ₙ—SiH₃. The silicon-containing compounds may also include compounds having the formula R—[(CR′₂)ₓ—(SiR″₂)_{y}—(CR′₂)_{z}]ₙ—R, where each R, R′, and R″ are independently a hydrogen (—H), an alkyl group (e.g., —CH₃, —CₘH₂ₘ₊₂, where m is a number from 1 to 10), an unsaturated alkyl group (e.g., —CH═CH₂), a silane group (e.g., —SiH₃, —(Si₂H₂)ₘ—SiH₃, where m is a number from 1 to 10), and where x, y and z are independently a number from 0 to 10, and n is a number from 0 to 10. In some instances, one or more of the R′ and/or R″ groups may have the formula —[(CH₂)ₓ—(SiH₂)_{y}—(CH₂)ₓ]ₙ—R′″, wherein R′″ is a hydrogen (—H), alkyl group (e.g., —CH₃, —CₘH₂ₘ₊₂, where m is a number from 1 to 10), unsaturated alkyl group (e.g., —CH═CH₂), or silane group (e.g., —SiH₃, —(Si₂H₂)ₘ—SiH₃, where m is a number from 1 to 10)), and where x, y, and z are independently a number from 0 to 10, and n is a number from 0 to 10.

Still more exemplary silicon-containing precursors may include silylalkanes and silylalkenes such as R₃Si—[CH₂]ₙ—SiR₃, wherein n may be an integer from 1 to 10, and each of the R groups are independently a hydrogen (—H), methyl (—CH₃), ethyl (—C₂CH₃), ethylene (—CHCH₂), propyl (—CH₂CH₂CH₃), isopropyl (—CHCH₃CH₃), etc. They may also include silacyclopropanes, silacyclobutanes, silacyclopentanes, silacyclohexanes, silacycloheptanes, silacyclooctanes, silacyclononanes, silacyclopropenes, silacyclobutenes, silacyclopentenes, silacyclohexenes, silacycloheptenes, silacyclooctenes, silacyclononenes, etc. Specific examples of these precursors may include without limitation the following structures:

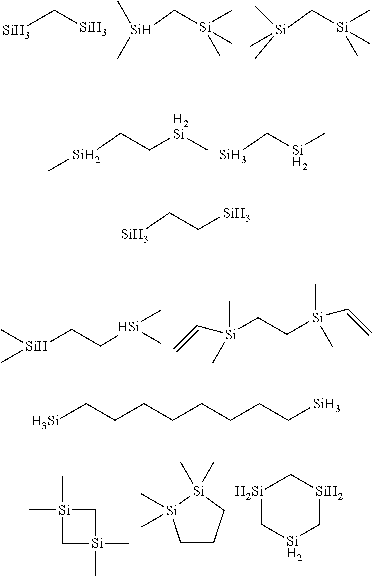

Exemplary silicon-containing precursors may further include one or more silane groups bonded to a central carbon atom or moiety. These exemplary precursors may include compounds of the formula H_{4-x-y}CX_{y}(SiR₃)ₓ, where x is 1, 2, 3, or 4, y is 0, 1, 2 or 3, each X is independently a hydrogen or halogen (e.g. F, Cl, Br), and each R is independently a hydrogen (—H) or an alkyl group. Exemplary precursors may further include compounds where the central carbon moiety is a C₂-C₆ saturated or unsaturated alkyl group such as a (SiR₃)ₓC═C(SiR₃)ₓ, where x is 1 or 2, and each R is independently a hydrogen (—H) or an alkyl group. Specific examples of these precursors may include without limitation the following structures:

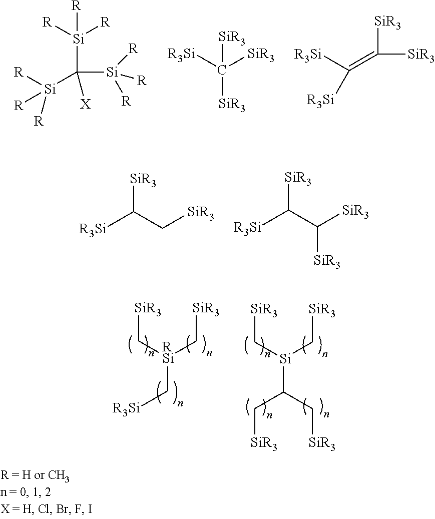

where X may be a hydrogen or a halogen (e.g., F, Cl, Br).

The silicon-containing precursors may also include nitrogen moieties. For example the precursors may include Si—N and N—Si—N moieties that are substituted or unsubstituted. For example, the precursors may include a central Si atom bonded to one or more nitrogen moieties represented by the formula R₄₋ₓSi(NR₂)ₓ, where x may be 1, 2, 3, or 4, and each R is independently a hydrogen (—H) or an alkyl group. Additional precursors may include a central N atom bonded to one or more Si-containing moieties represented by the formula R_{4-y}N(SiR₃)_{y}, where y may be 1, 2, or 3, and each R is independently a hydrogen (—H) or an alkyl group. Further examples may include cyclic compounds with Si—N and Si—N—Si groups incorporated into the ring structure. For example, the ring structure may have three (e.g., cyclopropyl), four (e.g., cyclobutyl), five (e.g., cyclopentyl), six (e.g., cyclohexyl), seven (e.g., cycloheptyl), eight (e.g., cyclooctyl), nine (e.g., cyclononyl), or more silicon and nitrogen atoms. Each atom in the ring may be bonded to one or more pendant moieties such as hydrogen (—H), an alkyl group (e.g., —CH₃), a silane (e.g., —SiR₃), an amine (—NR₂), among other groups. Specific examples of these precursors may include without limitation the following structures:

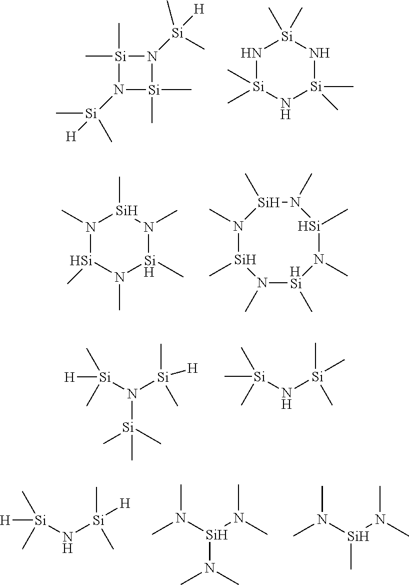

In embodiments where there is a desire to form the Si—C—N film with low (or no) oxygen concentration, the silicon-precursor may be selected to be an oxygen-free precursor that contains no oxygen moieties. In these instances, conventional silicon CVD precursors, such as tetraethyl orthosilicate (TEOS) or tetramethyl orthosilicate (TMOS), would not be used as the silicon-containing precursor.

Additional embodiments may also include the use of a carbon-free silicon source such as silane (SiH₄), and silyl-amines (e.g., N(SiH₃)₃) among others. The carbon source may come from a separate precursor that is either independently provided to the deposition chamber or mixed with the silicon-containing precursor. Exemplary carbon-containing precursors may include organosilane precursors, and hydrocarbons (e.g., methane, ethane, etc.). In some instances, a silicon-and-carbon containing precursor may be combined with a carbon-fee silicon precursor to adjust the silicon-to-carbon ratio in the deposited film.

In addition to the silicon-containing precursor, an energized nitrogen-containing precursor may added to the deposition chamber 104. The energized nitrogen-containing precursor may contribute some or all of the nitrogen constituent in the deposited Si—C—N film. A nitrogen-containing precursor is flowed into a remote plasma to form plasma effluents, aka the energized nitrogen-containing precursor. Exemplary sources for the nitrogen-containing precursor may include ammonia (NH₃), hydrazine (N₂H₄), amines, NO, N₂O, and NO₂, among others. The nitrogen-containing precursor may be accompanied by one or more additional gases such a hydrogen (H₂), nitrogen (N₂), helium, neon, argon, etc. The nitrogen-precursor may also contain carbon that provides at least some of the carbon constituent in the deposited Si—C—N layer Exemplary nitrogen-precursors that also contain carbon include alkyl amines. In some instances the additional gases may also be at least partially dissociated and/or radicalized by the plasma, while in other instances they may act as a dilutant/carrier gas.

The nitrogen-containing precursor may be energized by a plasma formed in a remote plasma system (RPS) that's positioned outside the deposition chamber. The nitrogen-containing source may be exposed to the remote plasma where it is dissociated, radicalized, and/or otherwise transformed into the energized nitrogen-containing precursor. For example, when the source of nitrogen-containing precursor is NH₃, energized nitrogen-containing precursor may include one or more of .N, .NH, .NH₂, nitrogen radicals. The energized precursor is then introduced to the deposition chamber, where it may mix for the first time with the independently introduced silicon-containing precursor.

Alternatively (or in addition), the nitrogen-containing precursor may be energized in a plasma region inside the deposition chamber. This plasma region may be partitioned from the deposition region where the precursors mix and react to deposit the flowable Si—C—N film on the exposed surfaces of the substrate. In these instances, the deposition region may be described as a “plasma free” region during the deposition process. It should be noted that “plasma free” does not necessarily mean the region is devoid of plasma. The borders of the plasma in the chamber plasma region are hard to define and may encroach upon the deposition region through, for example, the apertures of a showerhead if one is being used to transport the precursors to the deposition region. If an inductively-coupled plasma is incorporated into the deposition chamber, a small amount of ionization may be initiated in the deposition region during a deposition.

Once in the deposition chamber, the energized nitrogen-containing precursor and the silicon-containing precursor may react 106 to form a flowable Si—C—N layer on the substrate. The temperature in the reaction region of the deposition chamber may be low (e.g., less than 100° C.) and the total chamber pressure may be about 0.1 Torr to about 10 Torr (e.g., about 0.5 to about 6 Torr, etc.) during the deposition of the Si—C—N film. The temperature may be controlled in part by a temperature controlled pedestal that supports the substrate. The pedestal may be thermally coupled to a cooling/heating unit that adjust the pedestal and substrate temperature to, for example, about 0° C. to about 150° C.

The initially flowable Si—C—N layer may be deposited on exposed planar surfaces a well as into gaps. The deposition thickness may be about 50 Å or more (e.g., about 100 Å, about 150 Å, about 200 Å, about 250 Å, about 300 Å, about 350 Å, about 400 Å, etc.). The final Si—C—N layer may be the accumulation of two or more deposited Si—C—N layers that have undergone a treatment step before the deposition of the subsequent layer. For example, the Si—C—N layer may be a 1200 Å thick layer consisting of four deposited and treated 300 Å layers.

The flowability of the initially deposited Si—C—N layer may be due to a variety of properties which result from mixing an energized nitrogen-containing precursor with the silicon and carbon-containing precursor. These properties may include a significant hydrogen component in the initially deposited Si—C—N layer as well as the present of short-chained polysilazane polymers. The flowability does not rely on a high substrate temperature, therefore, the initially-flowable silicon-carbon-and-nitrogen-containing layer may fill gaps even on relatively low temperature substrates. During the formation of the silicon-carbon-and-nitrogen-containing layer, the substrate temperature may be below or about 400° C., below or about 300° C., below or about 200° C., below or about 150° C. or below or about 100° C. in embodiments of the invention.

When the flowable Si—C—N layer reaches a desired thickness, the process effluents may be removed from the deposition chamber. These process effluents may include any unreacted nitrogen-containing and silicon-containing precursors, dilutent and/or carrier gases, and reaction products that did not deposit on the substrate. The process effluents may be removed by evacuating the deposition chamber and/or displacing the effluents with non-deposition gases in the deposition region.

Following the initial deposition of the Si—C—N layer and optional removal of the process effluents, a treatment 108 may be performed to reduce the number of Si—H and/or C—H bonds in the layer, while also increasing the number of Si—Si, Si—C, Si—N, and/or C—N bonds. As noted above, a reduction in the number of these bonds may be desired after the deposition to harden the layer and increase its resistance to etching, aging, and contamination, among other forms of layer degradation. Treatment techniques may include exposing the initially deposited layer to a plasma of one or more treatment gases such as helium, nitrogen, argon, etc.

The plasma may be a capacitively-coupled plasma or a inductively-coupled plasma that is generated in-situ in the deposition region of the deposition chamber. For example, an inductively-coupled plasma treatment may be performed in an HDP-CVD deposition chamber, and a capacitively-coupled plasma may be performed in a plasma-enhanced CVD deposition chamber.

The plasma treatment may be done a comparable temperatures to the deposition of the Si—C—N layer. For example, the plasma treatment region of the chamber may be about 300° C. or less, about 250° C. or less, about 225° C. or less, about 200° C. or less, etc. For example, the plasma treatment region may have a temperature of about 100° C. to about 300° C. The temperature of the substrate may be about 25° C. or more, about 50° C. or more, about 100° C. or more, about 125° C. or more, about 150° C. or more, etc. For example, the substrate temperature may have a range of about 25° C. to about 150° C. The pressure in the plasma treatment region may depend on the plasma treatment (e.g., CCP versus ICP), but typically ranges on the order of mTorr to tens of Torr.

The treated Si—C—N layer may optionally be exposed to one or more etchants 110. The treated Si—C—N may have a wet-etch-rate-ratio (WERR) that is lower than the initially deposited flowable Si—C—N layer. A WERR may be defined as the relative etch rate of the Si—C—N layer (e.g., Å/min) in a particular etchant (e.g., dilute HF, hot phosphoric acid) compared to the etch rate of a thermally-grown silicon oxide layer formed on the same substrate. A WERR of 1.0 means the layer in question has the same etch rate as a thermal oxide layer, while a WERR of greater than 1 means the layer etches at a faster rate than thermal oxide. The plasma treatment makes the deposited Si—C—N layer more resistant to etching, thus reducing its WERR.

The treated Si—C—N layers may have increased etch resistance (i.e., lower WERR levels) to wet etchants for both silicon oxides and silicon nitrides. For example, the plasma treatment of the Si—C—N layer may lower the WERR level for dilute hydrofluoric acid (DHF), which is a conventional wet etchant for oxide, and may also lower the WERR level for hot phosphoric acid, which is a conventional wet etchant for nitride. Thus, the treated Si—C—N layers may make good blocking and/or etch stop layers for etch processes that include both oxide and nitride etching steps.

### Exemplary Deposition Systems

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

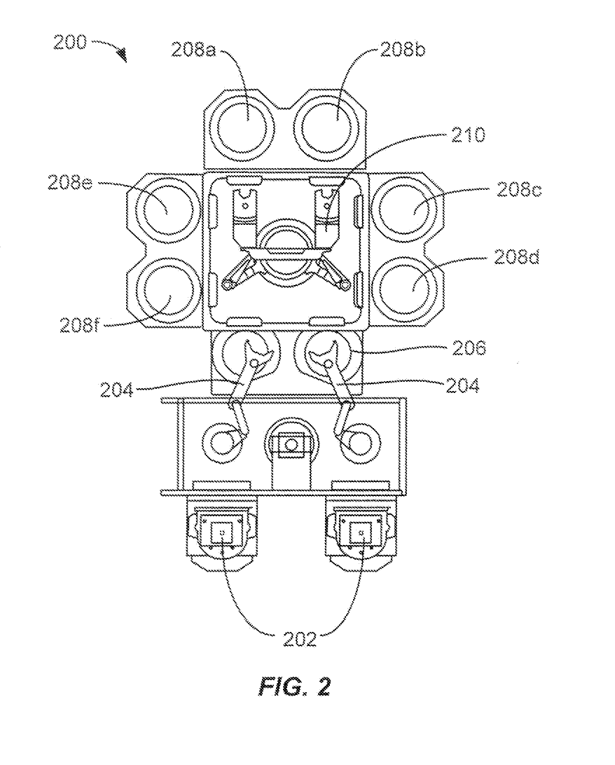

Embodiments of the deposition systems may be incorporated into larger fabrication systems for producing integrated circuit chips. FIG. 2 shows one such system 200 of deposition, baking and curing chambers according to disclosed embodiments. In the figure, a pair of FOUPs (front opening unified pods) 202 supply substrate substrates (e.g., 300 mm diameter wafers) that are received by robotic arms 204 and placed into a low pressure holding area 206 before being placed into one of the wafer processing chambers 208a-f. A second robotic arm 210 may be used to transport the substrate wafers from the holding area 206 to the processing chambers 208a-f and back.

The processing chambers 208a-f may include one or more system components for depositing, annealing, curing and/or etching a flowable dielectric film on the substrate wafer. In one configuration, two pairs of the processing chamber (e.g., 208c-d and 208e-t) may be used to deposit the flowable dielectric material on the substrate, and the third pair of processing chambers (e.g., 208a-b) may be used to anneal the deposited dielectric. In another configuration, the same two pairs of processing chambers (e.g., 208c-d and 208e-f) may be configured to both deposit and anneal a flowable dielectric film on the substrate, while the third pair of chambers (e.g., 208a-b) may be used for UV or E-beam curing of the deposited film. In still another configuration, all three pairs of chambers (e.g., 208a-f) may be configured to deposit and cure a flowable dielectric film on the substrate. In yet another configuration, two pairs of processing chambers (e.g., 208c-d and 208e-f) may be used for both deposition and UV or F-beam curing of the flowable dielectric, while a third pair of processing chambers (e.g. 208a-b) may be used for annealing the dielectric film. Any one or more of the processes described may be carried out on chamber(s) separated from the fabrication system shown in different embodiments.

In addition, one or more of the process chambers 208a-f may be configured as a wet treatment chamber. These process chambers include heating the flowable dielectric film in an atmosphere that includes moisture. Thus, embodiments of system 200 may include wet treatment chambers 208a-b and anneal processing chambers 208c-d to perform both wet and dry anneals on the deposited dielectric film.

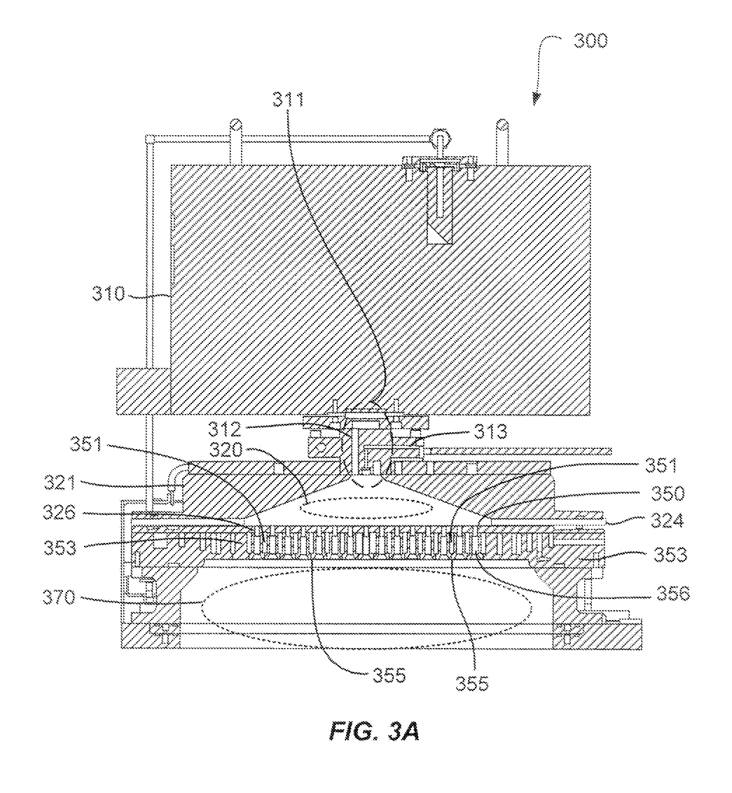

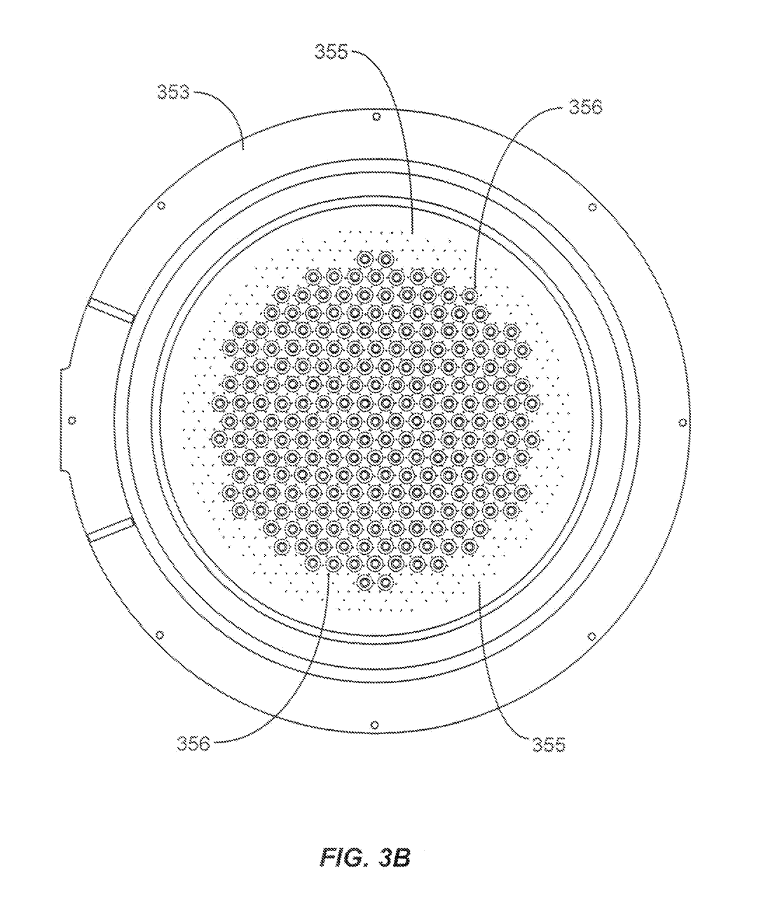

FIG. 3A is a substrate processing chamber 300 according to disclosed embodiments. A remote plasma system (RPS) 310 may process a gas which then travels through a gas inlet assembly 311. Two distinct gas supply channels are visible within the gas inlet assembly 311. A first channel 312 carries a gas that passes through the remote plasma system (RPS) 310, while a second channel 313 bypasses the RPS 310. The first channel 312 may be used for the process gas and the second channel 313 may be used for a treatment gas in disclosed embodiments. The lid (or conductive top portion) 321 and a perforated partition 353 are shown with an insulating ring 324 in between, which allows an AC potential to be applied to the lid 321 relative to perforated partition 353. The process gas travels through first channel 312 into chamber plasma region 320 and may be excited by a plasma in chamber plasma region 320 alone or in combination with RPS 310. The combination of chamber plasma region 320 and/or RPS 310 may be referred to as a remote plasma system herein. The perforated partition (also referred to as a showerhead) 353 separates chamber plasma region 320 from a substrate processing region 370 beneath showerhead 353. Showerhead 353 allows a plasma present in chamber plasma region 320 to avoid directly exciting gases in substrate processing region 370, while still allowing excited species to travel from chamber plasma region 320 into substrate processing region 370.

Showerhead 353 is positioned between chamber plasma region 320 and substrate processing region 370 and allows plasma effluents (excited derivatives of precursors or other gases) created within chamber plasma region 320 to pass through a plurality of through holes 356 that traverse the thickness of the plate. The showerhead 353 also has one or more hollow volumes 351 which can be filled with a precursor in the form of a vapor or gas (such as a silicon-containing precursor) and pass through small holes 355 into substrate processing region 370 but not directly into chamber plasma region 320. Showerhead 353 is thicker than the length of the smallest diameter 350 of the through-holes 356 in this disclosed embodiment. In order to maintain a significant concentration of excited species penetrating from chamber plasma region 320 to substrate processing region 370, the length 326 of the smallest diameter 350 of the through-holes may be restricted by forming larger diameter portions of through-holes 356 part way through the showerhead 353. The length of the smallest diameter 350 of the through-holes 356 may be the same order of magnitude as the smallest diameter of the through-holes 356 or less in disclosed embodiments.

In the embodiment shown, showerhead 353 may distribute (via through holes 356) process gases which contain oxygen, hydrogen and/or nitrogen and/or plasma effluents of such process gases upon excitation by a plasma in chamber plasma region 320. In embodiments, the process gas introduced into the RPS 310 and/or chamber plasma region 320 through first channel 312 may contain one or more of oxygen (O₂), ozone (O₃), N₂O, NO, NO₂, NH₃, NₓH_{y} including N₂H₄, silane, disilane, TSA, DSA, and alkyl amines. The process gas may also include a carrier gas such as helium, argon, nitrogen (N₂), etc. The second channel 313 may also deliver a process gas and/or a carrier gas, and/or a film-curing gas (e.g. O₃) used to remove an unwanted component from the growing or as-deposited film. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 356 may be between about 60 and about 2000. Through-holes 356 may have a variety of shapes but are most easily made round. The smallest diameter 350 of through holes 356 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 355 used to introduce a gas into substrate processing region 370 may be between about 100 and about 5000 or between about 500 and about 2000 in different embodiments. The diameter of the small holes 355 may be between about 0.1 mm and about 2 mm.

FIG. 3B is a bottom view of a showerhead 353 for use with a processing chamber according to disclosed embodiments. Showerhead 353 corresponds with the showerhead shown in FIG. 3A. Through-holes 356 are depicted with a larger inner-diameter (ID) on the bottom of showerhead 353 and a smaller ID at the top. Small holes 355 are distributed substantially evenly over the surface of the showerhead, even amongst the through-holes 356 which helps to provide more even mixing than other embodiments described herein.

An exemplary film is created on a substrate supported by a pedestal (not shown) within substrate processing region 370 when plasma effluents arriving through through-holes 356 in showerhead 353 combine with a silicon-containing precursor arriving through the small holes 355 originating from hollow volumes 351. Though substrate processing region 370 may be equipped to support a plasma for other processes such as curing, no plasma is present during the growth of the exemplary film.

A plasma may be ignited either in chamber plasma region 320 above showerhead 353 or substrate processing region 370 below showerhead 353. A plasma is present in chamber plasma region 320 to produce the radical nitrogen precursor from an inflow of a nitrogen-and-hydrogen-containing gas. An AC voltage typically in the radio frequency (RF) range is applied between the conductive top portion 321 of the processing chamber and showerhead 353 to ignite a plasma in chamber plasma region 320 during deposition. An RF power supply generates a high RF frequency of 13.56 MI-Hz but may also generate other frequencies alone or in combination with the 13.56 MHz frequency. Exemplary RF frequencies include microwave frequencies such as 2.4 GHz. The top plasma power may be greater than or about 1000 Watts, greater than or about 2000 Watts, greater than or about 3000 Watts or greater than or about 4000 Watts in embodiments of the invention, during deposition of the flowable film.

The top plasma may be left at low or no power when the bottom plasma in the substrate processing region 370 is turned on during the second curing stage or clean the interior surfaces bordering substrate processing region 370. A plasma in substrate processing region 370 is ignited by applying an AC voltage between showerhead 353 and the pedestal or bottom of the chamber. A cleaning gas may be introduced into substrate processing region 370 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the deposition system. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack (e.g. sequential deposition of a silicon-nitrogen-and-hydrogen-containing layer and then a silicon-oxygen-and-carbon-containing layer) on a substrate, converting a film to silicon oxide or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. The term “precursor” is used to refer to any process gas which takes part in a reaction to either remove material from or deposit material onto a surface. A gas in an “excited state” describes a gas wherein at least some of the gas molecules are in vibrationally-excited, dissociated and/or ionized states. A gas (or precursor) may be a combination of two or more gases (or precursors). A “radical precursor” is used to describe plasma effluents (a gas in an excited state which is exiting a plasma) which participate in a reaction to either remove material from or deposit material on a surface. A “radical-nitrogen precursor” is a radical precursor which contains nitrogen and a “radical-hydrogen precursor” is a radical precursor which contains hydrogen. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The term “gap” is used throughout with no implication that the etched geometry has a large horizontal aspect ratio. Viewed from above the surface, trenches may appear circular, oval, polygonal, rectangular, or a variety of other shapes. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

### Experimental

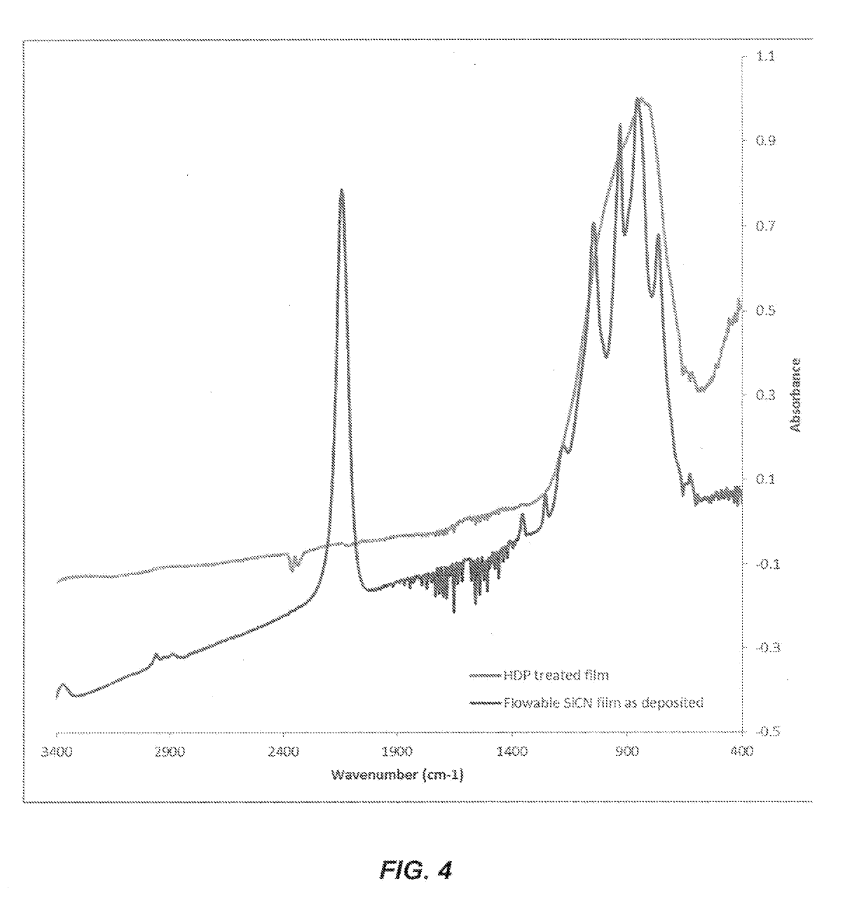

FIG. 4 shows an FTIR spectra of a deposited Si—C—N before and after being treated with an inductively-coupled plasma. The initially deposited flowable Si—C—N layer was deposited from a chemical vapor deposition of 1,3,5-trisilapentane and the plasma effluents of an ammonia gas mixture that was energized in a remote plasma unit outside the deposition chamber.

The plot in FIG. 4 shows the as-deposited flowable Si—C—N layer having a strong Si—H peak about 2250 cm⁻¹. Following the HDP plasma treatment, the peak has almost completely disappeared, indicating most (if not all) the Si—H bonds in the initial flowable layer have been removed by the plasma treatment.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursors and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a dielectric layer on a semiconductor substrate, the method comprising:
providing a silicon-containing precursor and an energized nitrogen-containing precursor to a chemical vapor deposition chamber;
reacting the silicon-containing precursor and the energized nitrogen-containing precursor in the chemical vapor deposition chamber to deposit a flowable silicon-carbon-nitrogen material on the substrate; and
treating the flowable silicon-carbon-nitrogen material to form the dielectric layer on the semiconductor substrate.

2. The method of claim 1, wherein the silicon-containing precursor comprises 1,3,5-trisilapentane, 1,4,7-trisilaheptane, disilacyclobutane, trisilacyclohexane, 3-methylsilane, silacyclopentene, silacyclobutene, or trimethylsilylacetylene.

3. The method of claim 1, wherein the silicon-containing precursor comprises:
(i) SiR₄, Si₂R₆, Si₃R₈, Si₄R₁₀, or Si₅R₁₂, wherein each R group is independently hydrogen (—H) or a saturated or unsaturated alkyl group;
(ii) a silylalkane or silylalkene having the formula R₃Si—[CH₂]ₙ—SiR₃, wherein n may be an integer from 1 to 10, and each of the R groups are independently a hydrogen (—H), or a saturated or unsaturated alkyl group;
(iii) a silylalkane or silylalkene having the formula R₃Si—[CH₂]ₓ—SiR₂—[CR₂]_{y}—SiR₃, wherein x and y are independently an integer from 1 to 10, and each of the R groups are independently a hydrogen (—H), or a saturated or unsaturated alkyl group;
(iv) a silacycloalkane or silacycloalkene selected from the group consisting of silacyclopropanes, silacyclobutanes, silacyclopentanes, silacyclohexanes, silacycloheptanes, silacyclooctanes, silacyclononanes, silacyclopropenes, silacyclobutenes, silacyclopentenes, silacyclohexenes, silacycloheptenes, silacyclooctenes, and silacyclononenes;
(v) H_{4-x-y}CX_{y}(SiR₃)ₓ, where x is 1, 2, 3, or 4, y is 0, 1, 2 or 3, each X is independently a hydrogen or halogen (e.g., F, Cl, Br), and each R is independently a hydrogen (—H) or an alkyl group;
(vi) (SiR₃)ₓC(SiR₃)ₓ, where x is 1 or 2, and each R is independently a hydrogen (—H) or an alkyl group; or
(vii) R—[(CR′₂)ₓ—(SiR″₂)_{y}—(CR′₂)_{z}]ₙ—R wherein each R, R′, and R″ are independently a hydrogen, an alkyl group, an unsaturated alkyl group, a silane group, or
—[(CH₂)ₓ₁—(SiH₂)_{y1}—(CH₂)_{z1}]ₙ₁—R′″ wherein x1, y1 and z1 are independently a number from 0 to 10, and n1 is a number from 0 to 10,
and wherein x, y and z are independently a number from 0 to 10, and n is a number from 0 to 10.

4. The method of claim 1, wherein the silicon-containing precursor comprises a silicon-and-nitrogen containing precursor selected from the group consisting of:
(i) R₄₋ₓSi(NR₂)ₓ, where x may be 1, 2, 3, or 4, and each R is independently a hydrogen (—H) or an alkyl group;
(ii) R_{4-y}N(SiR₃)_{y}, where y may be 1, 2, or 3, and each R is independently a hydrogen (—H) or an alkyl group; or
(iii) an substituted or unsubstituted ring structure comprising at least one Si atom and at least one nitrogen atom in the ring.

5. The method of claim 1, wherein the silicon-containing precursor comprises one of 1,3,5-trisilapentane or 1,4,7-trisilaheptane.

6. The method of claim 1, wherein the energized nitrogen-containing precursor comprises energized ammonia or an energized fragment of ammonia.

7. The method of claim 1, wherein the energized ammonia is produced in a remote plasma system fluidly coupled to the chemical vapor deposition chamber.

8. The method of claim 1, wherein the flowable silicon-carbon-nitrogen material comprises Si—H bonds.

9. The method of claim 8, wherein the treating of the flowable silicon-carbon-nitrogen material reduces the number of Si—H bonds in the material.

10. The method of claim 1, wherein the treating of the flowable silicon-carbon-nitrogen material comprises exposing the material to a plasma.

11. The method of claim 10, wherein the plasma for treating the flowable silicon-carbon-nitrogen material is located in the chemical vapor deposition chamber.

12. The method of claim 10, wherein the plasma is an inductively-coupled plasma or a capacitively-coupled plasma.

13. A method of treating a flowable silicon-carbon-nitrogen layer to reduce a wet etch rate ratio (WERR) of the layer, the method comprising:
forming the flowable silicon-carbon-nitrogen layer on a substrate by chemical vapor deposition of a silicon-containing precursor and an activated nitrogen precursor;
exposing the flowable silicon-carbon-nitrogen layer to plasma, wherein the plasma exposure reduces the number of Si—H bonds and increases the number of Si—C bonds in the layer, and wherein the plasma exposure reduces the WERR of the layer.

14. The method of claim 13, wherein the flowable silicon-containing precursor comprises 1,3,5-trisilapentane, 1,4,7-trisilaheptane, disilacyclobutane, trisilacyclohexane, 3-methylsilane, silacyclopentene, silacyclobutene, or trimethylsilylacetylene.

15. The method of claim 13, wherein the flowable silicon-containing precursor comprises:
(i) SiR₄, Si₂R₆, Si₃R₈, Si₄R₁₀, or Si₅R₁₂, wherein each R group is independently hydrogen (—H) or a saturated or unsaturated alkyl group;
(ii) a silylalkane or silylalkene having the formula R₃Si—[CH₂]ₙ—SiR₃, wherein n may be an integer from 1 to 10, and each of the R groups are independently a hydrogen (—H), or a saturated or unsaturated alkyl group;
(iii) a silylalkane or silylalkene having the formula R₃Si—[CR₂]ₓ—SiR₂—[CR₂]_{y}—SiR₃, wherein x and y are independently an integer from 1 to 10, and each of the R groups are independently a hydrogen (—H), or a saturated or unsaturated alkyl group;
(iv) a silacycloalkane or silacycloalkene selected from the group consisting of silacyclopropanes, silacyclobutanes, silacyclopentanes, silacyclohexanes, silacycloheptanes, silacyclooctanes, silacyclononanes, silacyclopropenes, silacyclobutenes, silacyclopentenes, silacyclohexenes, silacycloheptenes, silacyclooctenes, and silacyclononenes;
(v) H_{4-x-y}CX_{y}(SiR₃)ₓ, where x is 1, 2, 3, or 4, y is 0, 1, 2 or 3, each X is independently a hydrogen or halogen (e.g., F, Cl, Br), and each R is independently a hydrogen (—H) or an alkyl group;
(vi) (SiR₃)ₓC═C(SiR₃)ₓ, where x is 1 or 2, and each R is independently a hydrogen (—H) or an alkyl group; or
(vii) R—[(CR′₂)ₓ—(SiR″₂)_{y}—(CR′₂)_{z}]ₙ—R, wherein each R, R′, and R″ are independently a hydrogen, an alkyl group, an unsaturated alkyl group, a silane group, or
—[(CH₂)ₓ₁—(SiH₂)_{y1}—(CH₂)_{z1}]ₙ₁—R′″ wherein x1, y1 and z1 are independently a number from 0 to 10, and n1 is a number from 0 to 10,
and wherein x, y and z are independently a number from 0 to 10, and n is a number from 0 to 10.

16. The method of claim 13, wherein the flowable silicon-containing precursor comprises a silicon-and-nitrogen containing precursor selected from the group consisting of:
(i) R₄₋ₓSi(NR₂)ₓ, where x may be 1, 2, 3, or 4, and each R is independently a hydrogen (—H) or an alkyl group;
(ii) R_{4-y}N(SiR₃)_{y}, where y may be 1, 2, or 3, and each R is independently a hydrogen (—H) or an alkyl group; or
(iii) an substituted or unsubstituted ring structure comprising at least one Si atom and at least one nitrogen atom in the ring.

17. The method of claim 13, wherein the activated nitrogen precursor comprises ammonia or an ammonia fragment that has been exposed to a plasma.

18. The method of claim 13, wherein the plasma exposure reduces the number of C—H bonds and increases the number of Si—Si bonds, Si—N bonds, and C—N bonds in the silicon-carbon-nitrogen layer.

19. The method of claim 13, wherein the plasma is an inductively-coupled plasma or a capacitively-coupled plasma.

20. The method of claim 13, wherein the plasma exposure decreases the WERR of the silicon-carbon-nitrogen layer in both dilute hydrofluoric acid and hot phosphoric acid.
